(19) United States
(12) Patent Application Publication
(10) Pub. No.: US 2026/0047479 A1
(43) Pub. Date: Feb. 12, 2026

(54) PACKAGE AND METHOD OF FORMING A PACKAGE

(71) Applicant: Infineon Technologies AG, Neubiberg (DE)

(72) Inventors: Yosephine Andriani, Central Java (ID); Stefan Schwab, Regensburg (DE)

(21) Appl. No.: 19/282,403

(22) Filed: Jul. 28, 2025

(30) Foreign Application Priority Data
Aug. 6, 2024 (DE) 102024122456.8

(51) Int. Cl. H01L 23/29; H01L 21/56; H01L 23/31

(52) U.S. Cl. CPC H01L 23/29; H01L 21/56; H01L 23/3135; H01L 23/3192

(57) ABSTRACT

A package is provided. The package includes an electronic chip and at least one magnesium hydroxide layer (Mg(OH)₂) over the electronic chip. A method of forming the package is also described.

### TECHNICAL FIELD

Various embodiments relate generally to a package and to a method of forming a package.

### BACKGROUND

Early (low voltage) TDDB (time dependent dielectric breakdown) failure may hinder a qualification of a package and may result in a low maximum working insulation voltage (V_{IORM}) value. Regardless of the starting point of an electrical tree in a package, a breakdown path of electrical treeing tends to proceed in between a polyimide/oxide interface, leading to an erosion of the oxide and, as a consequence, possibly to a device failure. Examples of packages that may show such a behaviour include surface mounted devices.

The common material solutions are mainly focused on modifying a composition of an epoxy molding compound (EMC) used in the package. For example by adding additives (voltage stabilizer, antioxidant, UV absorber), by improving a filler/epoxy interfacial bond, by using smaller filler size as crack pinner/deflector, and/or by removing carbon black from the EMC composition. An improvement of TDDB performance may be observed.

However, a direct contact of electrical tree with the active material is often mandatory for its effectiveness and a random occurrence by nature. In addition, these methods are effective to hinder the growth of electrical treeing within EMC. However, it is unable to stop the treeing progression outside the EMC.

### SUMMARY

A package is provided. The package may include an electronic chip, and at least one magnesium hydroxide layer (Mg(OH)₂) over the electronic chip.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic cross-sectional view of a portion of a package in accordance with various embodiments;

FIG. 1B shows a schematic cross-sectional view of a portion of a package of a prior art;

FIG. 2A shows a schematic cross-sectional view of a portion of a package in accordance with various embodiments;

FIG. 2B shows a schematic cross-sectional view of a portion of a package of a prior art;

FIGS. 3A to 3G each show a schematic cross-sectional view of a package in accordance with various embodiments;

FIGS. 4A and 4B both show a schematic cross-sectional view of a package in accordance with various embodiments; and

FIG. 5 shows a flow diagram of a method of forming a package in accordance with various embodiments.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In various embodiments, a package is provided that includes a chip (the package may thus also be referred to as “chip package”) and a magnesium hydroxide layer (Mg(OH)₂) over the electronic chip.

As an alternative to the magnesium hydroxide layer or in addition to it, a different metal hydroxide material, a Schiff base metal complex (e.g. nickel based, copper-based), MnO₂, or Al-doped ZnO may be used, since several other metal hydroxide materials (e.g., metal hydroxides that are formed as porous layers), Schiff base metal complexes, MnO₂, and Al-doped ZnO have properties that are similar to at least some properties of magnesium hydroxide and make them suitable for the herein described embodiments. Some of these different materials are listed or mentioned below. In this description, the magnesium hydroxide is specifically mentioned as being part of the package of various embodiments, and as being used in a method of forming a package in accordance with various embodiments. Unless specifically mentioned otherwise or clear from the context that this is not the case, it is to be understood that any of the specified metal hydroxides, Schiff base materials, MnO₂, or Al-doped ZnO may be used instead of or in combination with the magnesium hydroxide, and that the respective material may provide, mutatis mutandis, any or all of the functions of the magnesium hydroxide.

The magnesium hydroxide layer may be arranged in order to restrict a growth of electrical trees at interfaces outside an encapsulation material (e.g., a mold compound, e g., an epoxy mold compound (EMC)) of the package.

In various embodiments, a magnesium hydroxide layer may be incorporated at interfaces in a package that are prone to electrical treeing, such as an oxide/imide interface, and/or an imide/encapsulation material interface, or a chip/encapsulation material interface. The presence of the magnesium hydroxide layer in the package, e.g., at the above described positions, may hinder a progression of electrical treeing by any, some, or all of the following mechanisms:
(1) Magnesium hydroxide can act as a flame retardant: magnesium hydroxide, when subjected to a sparking event, may provide an endothermic reaction:

Mg(OH)₂→MgO+H₂O (1389 J/g):

The endothermic reaction may absorb heat and thereby take energy out of the system, which reduces treeing.
(2) Magnesium hydroxide may be applied by atomic layer deposition (ALD), and a surface roughness of the ALD layer may have a value that lengthens the breakdown path (e.g., a surface structure of the magnesium hydroxide may contain pores and may for example have a surface roughness in a range from about 30 nm≤Ra≤1000 nm, for example in a range from about 50 nm≤Ra≤500 nm) and
(3) Magnesium hydroxide may improve an imide/oxide interfacial interaction (interlocking mechanism).

In various embodiments, the package, e.g., a semiconductor package, may include a sandwiched flame retardant like magnesium hydroxide for an improved TDDB performance. This may in particular apply to packages for high voltage applications and/or packages using wide bandgap materials.

In various embodiments, a magnesium hydroxide layer may be deposited as an ALD layer (followed by a hot water dipping process) between an oxide and an imide.

In various embodiments, a magnesium hydroxide layer may be deposited as an ALD layer (followed by a hot water dipping process) between an encapsulation material. (e.g., a mold compound, e.g., an EMC) and an imide.

Irrespective of where the magnesium hydroxide layer is formed, e.g., between oxide and imide and/or between encapsulation material and imide, the process of forming the magnesium hydroxide layer may include depositing an ALD layer made out of magnesium oxide, which is then transformed into magnesium hydroxide by hot water treatment (e.g., dipping into hot water). The transformation towards magnesium hydroxide might happen only on part of the layer (e.g. an outer part that is in contact with the hot water), while the bottom of the layer may still include or consist of magnesium oxide.

In various embodiments, a magnesium hydroxide layer may be deposited (e.g., as a flame retardant) between an oxide and an imide, and/or between a mold compund and an imide, optionally in combination with other ALD layers (e.g. ZrO₂, HfO₂) as intermediate layers to increase an electrical barrier function. The additional layers may be formed at interfaces and may further improve a high voltage (HV) stability.

In various embodiments, an increasing of electrical barrier function may be achieved, in particular by providing porous layers at material interfaces, e.g. between oxide and imide and/or between imide and mold compound.

A short (or at least shorter) path of treeing at a mold compound—imide interface and/or at an oxide—imide interface may be achieved by various embodiments.

In various embodiments, the package may include a plurality of magnesium hydroxide layers: at different interfaces of the package as mentioned above (e.g., imide—oxide interface and imide—mold compound interface), and/or by forming any or each of the magnesium hydroxide layers as a layer stack of magnesium hydroxide layers, which may for example be formed by repeating a process of forming a magnesium oxide layer and applying a hot water treatment to the magnesium oxide layer.

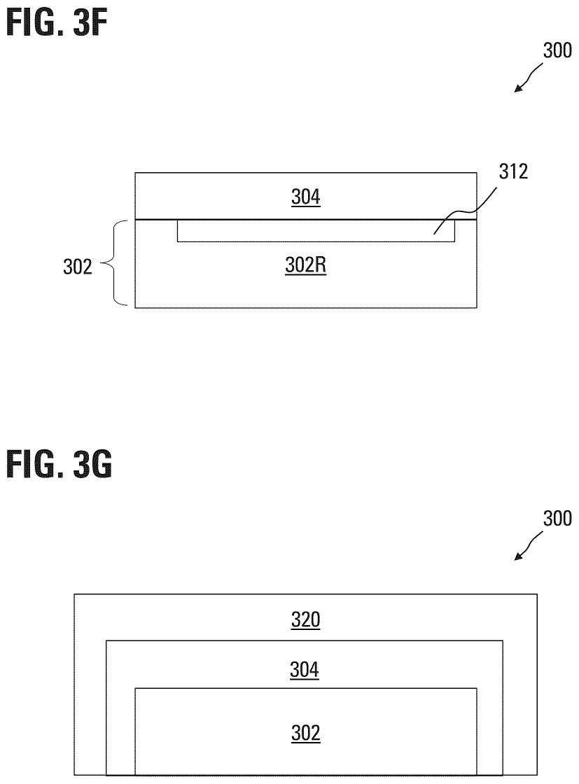

Each of FIGS. 3A to 3G shows a schematic cross-sectional view of a package 300 in accordance with various embodiments.

The package 300 may include an electronic chip 302 (chip for short), and at least one magnesium hydroxide layer (Mg(OH)₂) 304 over the electronic chip 302. The at least one magnesium hydroxide layer 304 may include a single layer (e.g., a magnesium hydroxide layer 304 applied during a single process, applied to only one side of the chip 302, a contiguous layer (with or without openings), and/or from a single material (which is straightforward when only magnesium hydroxide is considered, but may be relevant when the alternative materials are taken into account). The at least one magnesium hydroxide layer 304 may include a plurality of layers, e.g. a layer stack of magnesium hydroxide layers applied in sequential processes as mentioned above, layers (e.g., separate) arranged on different sides of the chip, discontinous layers, and/or layers of different materials (e.g., selected from a group that includes magnesium hydroxide and the alternative materials). For short, the at least one magnesium hydroxide layer 304 may be referred to as the magnesium hydroxide layer 304, but it is to be understood that any, some, or all of the above situations of having more than one magnesium hydroxide layer 304 may apply, unless this is specifically ruled out or clearly ruled out by the context.

The magnesium hydroxide layer 304 may cover a portion of a main surface of the electronic chip 302, may cover a complete main surface of the electronic chip 302 (as for example indicated by the black outline in FIG. 3A, or may cover additional portions of the chip 302, for example covering (partially or fully) the opposite main surface of the chip 302, and/or one or more, e.g., all, side surfaces of the chip 302. The magnesium hydroxide layer 304 that is optionally applied to the additional portions is indicated in grey in FIG. 3A. It is to be understood that a “full coverage” of the main surfaces of the chip 302 may nevertheless allow for electrically contacting the chip 302, e.g., by excluding the contact area, by forming the electrical contact through the thin magnesium hydroxide layer 304, or by applying the magnesium hydroxide layer 304 after forming the electrical contact (which may optionally include covering the electrical contact, e.g., a bond ball, a bonding wire or a clip, with the magnesium hydroxide).

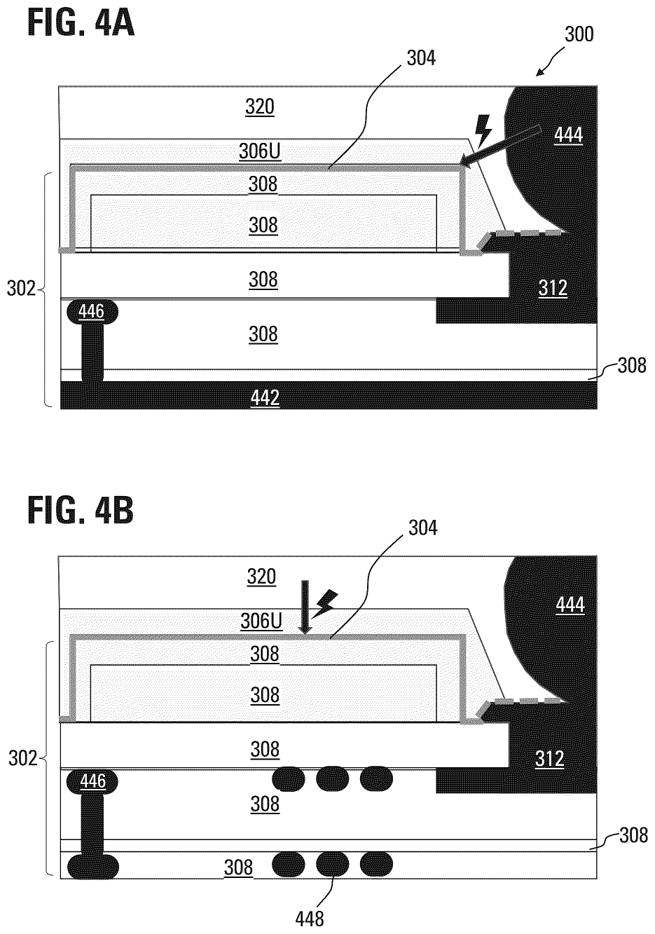

Each of FIGS. 4A and 4B shows a schematic cross-sectional view of a package 300 in accordance with various embodiments. Each of FIGS. 4A and 4B visualizes an embodiment in which the magnesium hydroxide layer 304 at least optionally (indicated as a dashed line) extends all the way to a ball bond 444.

In various embodiments, the magnesium hydroxide layer 304 may be applied directly to the electronic chip 302.

In various embodiments, a first layer 306L, 306U may be provided underneath and/or above the at least one magnesium hydroxide layer 304. The first layer 306L, 306U underneath the magnesium hydroxide layer 304 may be referred to as the first layer 306L (see FIG. 3C), and the first layer 306L, 306U underneath the magnesium hydroxide layer 304 may be referred to as the first layer 306U (see FIG. 3B).

The exemplary embodiment of FIG. 3D shows that both, the first layer above 306U and the first layer below 306L the magnesium hydroxide layer 304, may both be provided.

The first layer 306L, 306U may include or consist of an imide. The imide may be provided as a passivation/barrier layer for ions from an encapsulation material 320, e.g., a mold compound.

FIG. 3G visualizes an embodiment in which the magnesium hydroxide layer 304 is provided at an interface between the chip 302 and the encapsulation material 320.

Each of FIGS. 4A and 4B visualizes an embodiment in which the magnesium hydroxide layer 304 is provided at an interface between the chip 302 and the first layer 306U.

The encapsulation material 320 may include materials (e.g., a mold compound, e.g., an epoxy mold compound EMC) and may be formed by techniques essentially as known in the art. The encapsulation material 320 may at least partially encapsulate the electronic chip 302 and the at least one magnesium hydroxide layer 304. The encapsulation material 320.may be provided as a part of any package of embodiments described herein. In various embodiments, the encapsulation material 320 may form a common interface with the at least one magnesium hydroxide layer 304, for example as shown in FIG. 3G. In amendments to FIGS. 4A and 4B (not shown), the magnesium hydroxide layer 304 may, alternatively or additionally, be formed at the interface of the mold compound 320 and the first layer 306U (which would, in that case, make it a first layer 306L, because it would then be arranged underneath the magnesium hydroxide layer 304, or a first layer 306L/U, because it would be sandwiched between two magnesium hydroxide layers 304).

In various embodiments, the mold compound 320 may be modified, for example by including particles of magnesium hydroxide (Mg(OH)₂) and/or the alternative materials, in particular the alternative materials having flame retardant properties, for example aluminum oxide hydroxide (AlOOH), aluminum hydroxide (Al(OH)₃), and/or the Schiff base complexes. Thereby, a treeing resistance of the package 300 may be additionally increased.

In various embodiments, the chip 302, e.g., a top surface of the chip 302, may include a chip pad 312 (see FIG. 3F). The at least one magnesium hydroxide layer 304 may optionally at least partially cover the chip pad 312.

In the exemplary embodiments of FIGS. 4A and 4B, a dashed line visualizes an optional portion of the magnesium hydroxide layer 304 that may partially cover the chip pad 312.

In various embodiments, the electronic chip 302 may include at least one second layer 308 at least partially covering a side of the electronic chip 302 that faces the at least one magnesium hydroxide layer 304 (in the Figures, it is the top side).

The at least one second layer 308 may be arranged underneath the at least one magnesium hydroxide layer 304. In other words, the second layer 308 may be partially or fully covered by the magnesium hydroxide layer 304. FIG. 3E visualizes a corresponding embodiment.

In various embodiments, for example as shown in FIGS. 3E and 3F, certain portions of the chip 302 may be individually highlighted or illustrated, e.g., the second layer 308 in FIG. 3E or the chip pad 312 in FIG. 3F. In each case, the remaining portions of the chip 302 may be referred to as 302R. The remaining portions 302R may include all other portions of the chip 302, except the respective highlighted portion, for example a semiconductor base material in which semiconductor circuit elements may be formed, metallization layers 442, passivation layers (some of the second layer(s) 308 may form passivation layer), vias 446, coils 448, contact pads 312, etc. (see, e.g., FIGS. 4A and 4B).

In various embodiments, the at least one second layer 308 may include or consist of an oxide and/or a nitride, optionally silicon oxide, silicon nitride, zirconium oxide, and/or hafnium oxide.

As already outlined above, the presence of the magnesium hydroxide layer 304 at interfaces in the package 300 that are prone to electrical treeing, such as a chip 302 (with its second layer 308 oxide)/first layer imide 306 interface, and/or a first layer imide 306/encapsulation material 320 interface, or a chip 302 (with its second layer 308 oxide)/encapsulation material 320 interface may hinder a progression of electrical treeing by acting as a flame retardant, by increasing a surface roughness and thereby lengthening the breakdown path, and/or by improving a first layer imide 306/chip 302 (with its second layer 308 oxide) interfacial interaction (by providing an interlocking mechanism).

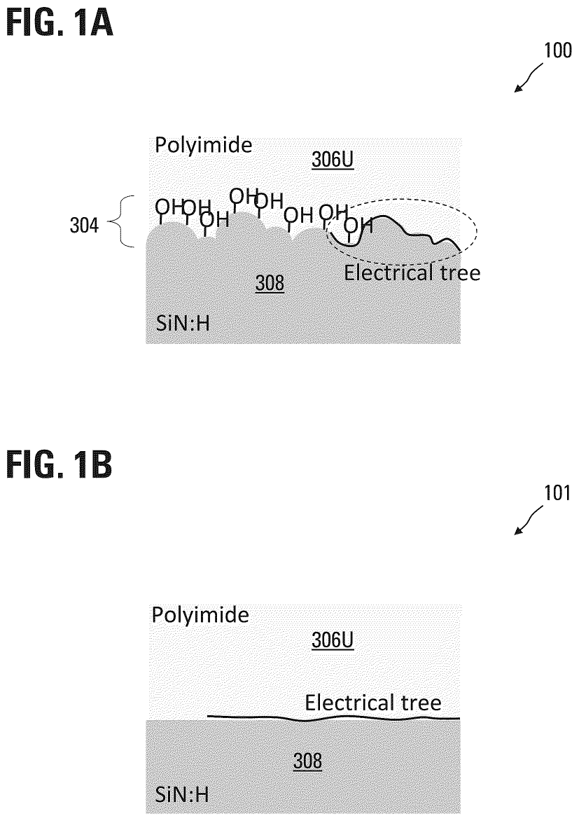

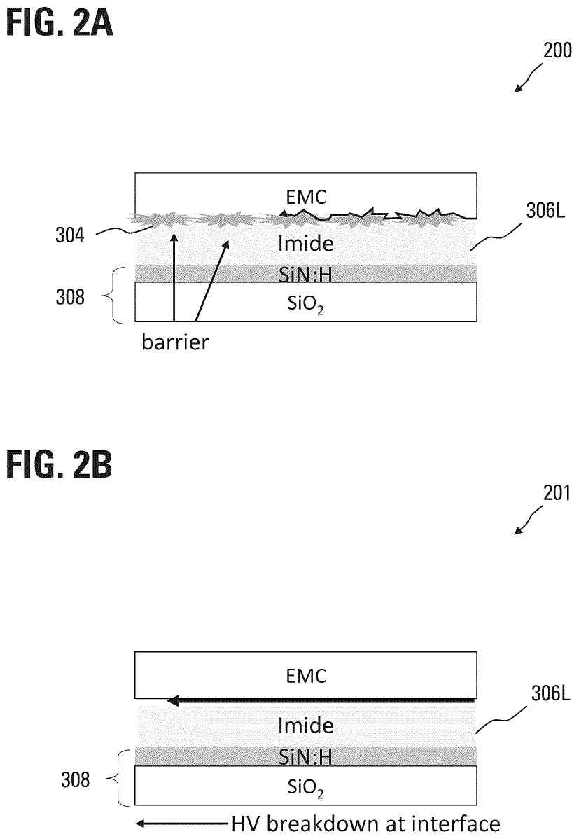

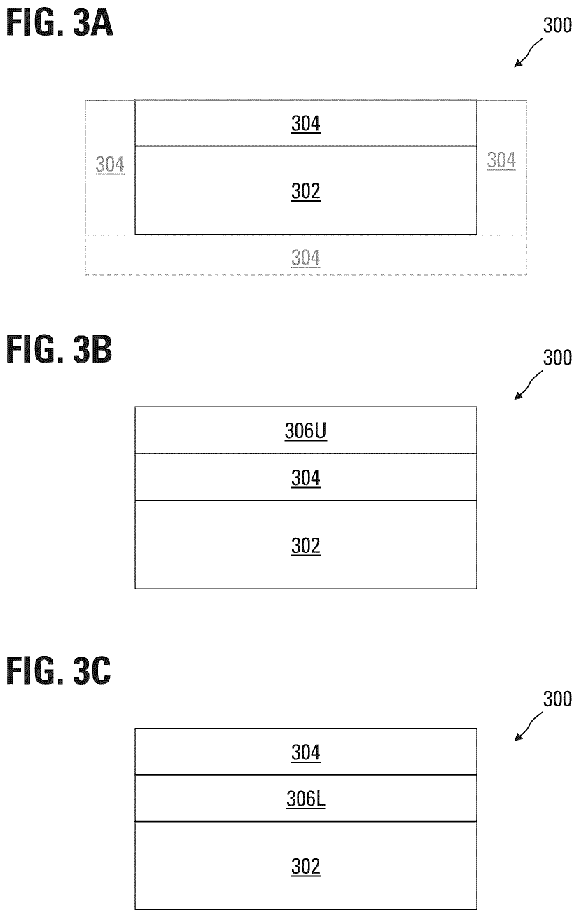

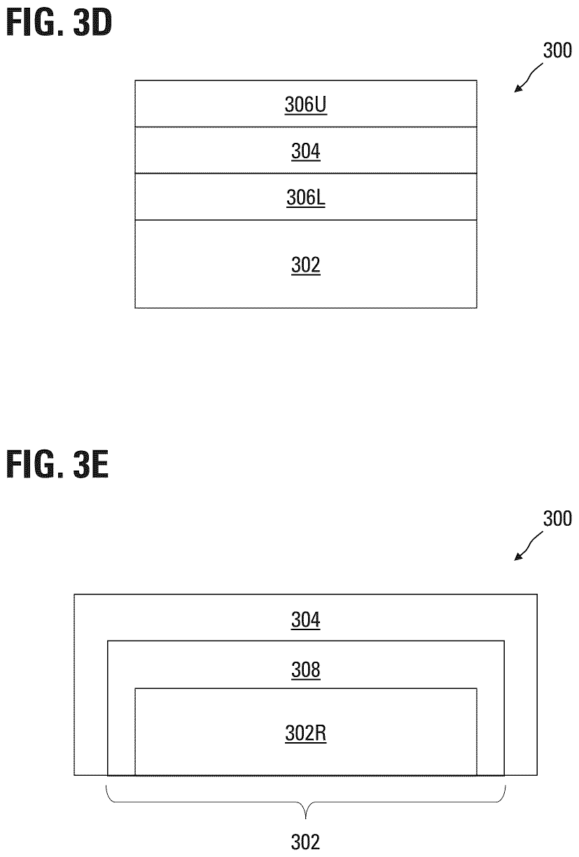

These mechanisms are illustrated in FIGS. 1A and 2A, each of which showing a schematic cross-sectional view of a portion 100 and 200, respectively of a package 300 in accordance with various embodiments, in comparison with FIGS. 1B and 2B, respectively, each of which showing a schematic cross-sectional view of a portion 101 and 201, respectively, of a package of a prior art.

As indicated in FIG. 1B, an electrical treeing (which may cause a breakdown of the package) may progress between a second layer 308 (in this case, a SiN:H-layer) of a chip 302 and a first layer 306U (in this case, an imide layer) of the package. The corresponding illustration of various embodiments shown in FIG. 1A visualizes the increased surface roughness lengthening the interface path and improving an interlock between the first layer 306U and the second layer 308 by the introduced magnesium hydroxide layer 304 (mainly indicated by the OH groups on the rough surface). The additional flame retardant function of the magnesium hydroxide material is not visualized, but additionally acts to shorten the eletrical treeing patch (indicated as a black arrow).

A similar comparison is provided in FIGS. 2A and 2B for the interface between the first layer 306L (in this case, an imide) and an encapsulation material 320 (in this case, an epoxy mold compound EMC).

Without the magnesium hydroxide layer 304, as shown for the prior art in FIG. 2B, the electrical treeing may smoothly progress between the first layer 306L and the encapsulation material 320.

In contrast to this, the magnesium hydroxide layer 304 arranged at the interface of the first layer 306L and the encapsulation material 320 may again increase a surface roughness lengthening the interface path and improving an interlock between the first layer 306L and the encapsulation material 320. The additional flame retardant function of the magnesium hydroxide material is not visualized, but additionally acts to shorten the eletrical treeing path (indicated as a black arrow).

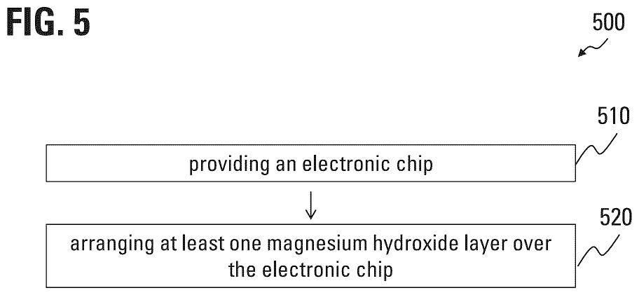

FIG. 5 shows a flow diagram 500 of a method of forming a package in accordance with various embodiments.

The method may include providing an electronic chip (in 510) and arranging at least one magnesium hydroxide layer over the electronic chip (in 520).

The arranging the at least one magnesium hydroxide layer may include forming a magnesium oxide layer, and subsequently, a hot water treatment, optionally a dipping into hot water.

As mentioned above, the at least one magnesium hydroxide layer may include a plurality of magnesium hydroxide layers that may form a layer stack. The layer stack may be formed by executing (e.g., successively) the forming the magnesium oxide layer and the subsequent hot water treatment for each of the plurality of magnesium hydroxide layers.

The forming the magnesium oxide layer may include at least one of a group of processes, the group consisting of: atomic layer deposition (ALD), electrochemical deposition (e.g., in an ion plating bath), and a sol-gel spin coating process.

The electronic chip may include at least one chip pad, and the method may further include electrically connecting a bonding element, e.g., a bonding wire and/or a clip, to the at least one chip pad. The arranging the at least one magnesium hydroxide layer may be performed before or after the electrically connecting the bonding element, e.g., the bonding wire and/or the clip.

In the case that the magnesium hydroxide layer is performed after the electrically connecting the bonding element, the magnesium hydroxide layer may optionally be formed at least partially covering the bonding element, e.g., the bonding wire and/or the clip.

As pointed out above, the at least one magnesium hydroxide layer 304 may be combined with or replaced by one or more of a group of alternative materials. Each of the alternative materials may exhibit at least one of the properties of the magnesium hydroxide that may improve a resistance to electrical treeing.

Even though some of these properties are considered to be known, the following list may not be limiting, since further effects—known or unknown—of the magnesium hydroxide and the alternative materials may improve the treeing resistance of the package. The list may include a flame retardant effect, an increase of an interface path length, and an improved interlock between adjacent layers.

Flame retardant materials may, besides the magnesium hydroxide (Mg(OH)₂), include at least the following: aluminum oxide hydroxide (AlOOH), aluminum hydroxide (Al(OH)₃), and Schiff base metal complexes.

Metals that can form porous metal hydroxide layers in hot water include the elemental metals Sn, Mg, Pb, Al, Zn, Fe, Sb, Mo, Cd, Mn, Co, Sc, Ni, V, Bi, Ta, Tl, Nd, Be, Cr, Er, Ti, In, and Cu, and the alloys and compounds Al #6061, Al #5052, plain steel, stainless steel, brass, and bronze.

Materials of high interest (since they can act as TDDB improvement as well acting as a flame retardant and as an adhesion promoter, and as the hot water treatment works very fast) include Sn, Mg, Zn, Ni (or their oxides/hydroxides, respectively).

Materials of medium interest (since they can act as TDDB improvement as well acting as a flame retardant and as an adhesion promoter, but the hot water treatment is a bit slower or needs higher temperatures) include Fe, Sb, Mn, Co, V, and Bi.

Elements that are depositable as oxide layers by ALD include the following:
SnO (e.g. (N, N′-diisopropylformamidinato tin(II)—precursor), MgO (e.g. Bis(ethylcyclopentadienyl)magnesium—precursor)—this may be used for forming the magnesium hydroxide layer 304), ZnO (e.g. Diethyl Zinc—precursor), and NiO (e.g. bis-methylcyclopentadienyl-nickel—precursor).

ALD-depositable materials that may form a porous/rough structure and may be used instead of or in addition to the magnesium hydroxide layer 304 for at least providing the increased interface path length and the adhesion promotion (the interlock properties) include (with their respective ALD-depositable precursors in parantheses) magnesium hydroxide Mg(OH)₂ (precursor MgO): Hydroxyapatite Ca₅(PO₄)₃OH (precursor CaCO₃), MnO₂ (precursor MnO; the MnO₂ may be formed after electrochemical oxidation of the MnO), and Al-doped ZnO (where the precursor is identical to the final layer).

Various examples will be illustrated in the following:

Example 1 is a package. The package may include an electronic chip, and at least one magnesium hydroxide layer (Mg(OH)₂) over the electronic chip.

In Example 2, the subject-matter of Example 1 may optionally include a first layer underneath and/or above the at least one magnesium hydroxide layer.

In Example 3, the subject-matter of Example 1 or 2 may optionally include that the first layer includes or consists of an imide.

In Example 4, the subject-matter of any of Examples 1 to 3 may optionally include that the electronic chip includes at least one second layer at least partially covering a side of the electronic chip that faces the at least one magnesium hydroxide layer, wherein the at least one second layer is arranged underneath the at least one magnesium hydroxide layer.

In Example 5, the subject-matter of Example 4 may optionally include that the at least one second layer includes or consists of an oxide and/or a nitride, optionally silicon oxide, silicon nitride, zirconium oxide, and/or hafnium oxide.

In Example 6, the subject-matter of any of Examples 1 to 5 may optionally include that the electronic chip includes a chip pad, and that the at least one magnesium hydroxide layer at least partially covers the chip pad.

In Example 7, the subject-matter of any of Examples 1 to 6 may optionally include that the at least one magnesium hydroxide layer fully or essentially fully encapsulates the electronic chip.

In Example 8, the subject-matter of any of Examples 1 to 7 may optionally further include an encapsulation material at least partially encapsulating the electronic chip and the at least one magnesium hydroxide layer.

In Example 9, the subject-matter of Example 8 may optionally include that the encapsulation material forms a common interface with the at least one magnesium hydroxide layer.

In Example 10, the subject-matter of Example 8 or 9 may optionally include that the encapsulation material includes a plurality of flame retardant particles.

In Example 11, the subject-matter of Example 10 may optionally include that the flame retardant includes or consist of at least one of a group of materials, the group consisting of: aluminum oxide hydroxide (AlOOH), aluminum hydroxide (Al(OH)₃), and magnesium hydroxide (Mg(OH)₂).

Example 12 is a method of forming a package. The method may include providing an electronic chip and arranging at least one magnesium hydroxide layer over the electronic chip.

In Example 13, the subject-matter of Example 12 may optionally include that the arranging the at least one magnesium hydroxide layer includes forming a magnesium oxide layer, and subsequently, a hot water treatment, optionally a dipping into hot water.

In Example 14, the subject-matter of Example 13 may optionally include that the at least one magnesium hydroxide layer includes a plurality of magnesium hydroxide layers, and that the forming the magnesium oxide layer and the subsequent hot water treatment is repeated for each of the plurality of magnesium hydroxide layers.

In Example 15, the subject-matter of Example 13 or 14 may optionally include that the forming the magnesium oxide layer includes at least one of a group of processes, the group consisting of: atomic layer deposition (ALD), electrochemical deposition, and a sol-gel spin coating process.

In Example 16, the subject-matter of any of Examples 12 to 15 may optionally include that the electronic chip includes at least one chip pad, and that the method further includes electrically connecting a bonding wire and/or a clip to the at least one chip pad.

In Example 17, the subject-matter of Example 16 may optionally include that the arranging the at least one magnesium hydroxide layer is performed before or after the electrically connecting the bonding wire and/or the clip.

In Example 18, the subject-matter of any of Examples 12 to 17 may optionally include thta the at least one magnesium hydroxide layer completely or essentially completely encapsulates the electronic chip.

In Example 19, the subject-matter of any of Examples 12 to 18 may optionally further include, after the arranging the at least one magnesium hydroxide layer, encapsulating the electronic chip with encapsulation material.

In Example 20, the subject-matter of Example 19 may optionally include that the encapsulation material is arranged to directly contact the at least one magnesium hydroxide layer.

In Example 21, the subject-matter of Example 19 or 20 may optionally include that the encapsulation material includes a plurality of flame retardant particles.

In Example 22, the subject-matter of any of Examples 12 to 21 may optionally further include arranging a first layer underneath and/or above the at least one magnesium hydroxide layer.

In Example 23, the subject-matter of Example 22 may optionally include that the first layer includes or consists of an imide.

In Example 24, the subject-matter of Example 22 or 23 may optionally include that the first layer is arranged to directly contact the at least one magnesium hydroxide layer.

In Example 25, the subject-matter of any of Examples 12 to 24 may optionally further include forming, as part of the electronic chip, at least one second layer at least partially covering a side of the electronic chip over which the at least one magnesium hydroxide layer is to be formed, wherein the at least one magnesium hydroxide layer is formed at least partially over the at least one second layer.

In Example 26, the subject-matter of Example 25 may optionally include that the at least one second layer includes or consists of an oxide and/or a nitride, optionally silicon oxide, silicon nitride, zirconium oxide, and/or hafnium oxide.

In Example 27, the subject-matter of Example 25 or 26 may optionally include the arranging the first layer of any of Examples 22 to 24, wherein the first layer is arranged over the at least one second layer.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A package, comprising:
an electronic chip; and
at least one magnesium hydroxide layer over the electronic chip.

2. The package of claim 1, further comprising:
a first layer underneath and/or above the at least one magnesium hydroxide layer.

3. The package of claim 2,
wherein the first layer comprises an imide.

4. The package of claim 1,
wherein the electronic chip comprises at least one second layer at least partially covering a side of the electronic chip that faces the at least one magnesium hydroxide layer, and
wherein the at least one second layer is arranged underneath the at least one magnesium hydroxide layer.

5. The package of claim 4,
wherein the at least one second layer comprises an oxide and/or a nitride.

6. The package of claim 1,
wherein the electronic chip comprises a chip pad, and
wherein the at least one magnesium hydroxide layer at least partially covers the chip pad.

7. The package of claim 1,
wherein the at least one magnesium hydroxide layer fully or essentially fully encapsulates the electronic chip.

8. The package of claim 1, further comprising:
an encapsulation material at least partially encapsulating the electronic chip and the at least one magnesium hydroxide layer.

9. The package of claim 8,
wherein the encapsulation material forms a common interface with the at least one magnesium hydroxide layer.

10. A method of forming a package, the method comprising:
providing an electronic chip; and
arranging at least one magnesium hydroxide layer over the electronic chip.

11. The method of claim 10, wherein arranging the at least one magnesium hydroxide layer over the electronic chip comprises:
forming a magnesium oxide layer; and
after forming the magnesium oxide layer, performing a hot water treatment.

12. The method of claim 11,
wherein the at least one magnesium hydroxide layer comprises a plurality of magnesium hydroxide layers,
wherein forming the magnesium oxide layer and performing the hot water treatment are repeated for each of the plurality of magnesium hydroxide layers.

13. The method of claim 11,
wherein forming the magnesium oxide layer comprises at least one of a group of processes consisting of:
atomic layer deposition;
electrochemical deposition; and
a sol-gel spin coating process.

14. The method of claim 10,
wherein the electronic chip comprises at least one chip pad, and
wherein the method further comprises electrically connecting a bonding wire and/or a clip to the at least one chip pad.

15. The method of claim 14,
wherein arranging the at least one magnesium hydroxide layer over the electronic chip is performed before or after the electrically connecting the bonding wire and/or the clip.

16. The method of claim 10,
wherein the at least one magnesium hydroxide layer completely or essentially completely encapsulates the electronic chip.

17. The method of claim 10, further comprising:
after arranging the at least one magnesium hydroxide layer over the electronic chip, encapsulating the electronic chip with an encapsulation material.

18. The method of claim 10, further comprising:
arranging a first layer underneath and/or above the at least one magnesium hydroxide layer.

19. The method of claim 18,
wherein the first layer comprises an imide.

20. The method of claim 18,
wherein the first layer is arranged to directly contact the at least one magnesium hydroxide layer.

21. The method claim 10, further comprising:
forming, as part of the electronic chip, at least one second layer at least partially covering a side of the electronic chip over which the at least one magnesium hydroxide layer is to be formed,
wherein the at least one magnesium hydroxide layer is formed at least partially over the at least one second layer.

22. The method of claim 21,
wherein the at least one second layer comprises an oxide and/or a nitride.

23. The method of claim 21, further comprising:
arranging a first layer underneath and/or above the at least one magnesium hydroxide layer,
wherein the first layer is arranged over the at least one second layer.
